(19) United States
(12) Patent Application Publication
(10) Pub. No.: US 2008/0197353 A1
(43) Pub. Date: Aug. 21, 2008

(54) SEMICONDUCTOR DEVICE FOR WHICH ELECTRICAL TEST IS PERFORMED WHILE PROBE IS IN CONTACT WITH CONDUCTIVE PAD

(75) Inventors: Yasufumi TAKAHASHI, Kawasaki (JP); Kouichi NAGAI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/035,071

(22) Filed: Feb. 21, 2008

(30) Foreign Application Priority Data
Feb. 21, 2007 (JP) 2007-040324

(51) Int. Cl. H01L 21/66; H01L 23/58

(52) U.S. Cl. 257/48; 438/18; 257/E21.523; 257/E21.531

(57) ABSTRACT

A semiconductor device that comprises a conductive pad that is provided on the insulating film and that is obtained by forming a main conductive film and a surface conductive film harder than the main conductive film in that order.

### CROSS REFERENCES TO RELATED APPLICATIONS

This application is based upon and claims the benefit of priority from the prior Japanese Patent Application No. 2007-40324, filed on Feb. 21, 2007, the entire contents of which are incorporated herein by reference.

### FIELD OF THE INVENTION

The present invention relates to a semiconductor device for which an electrical test is performed while a conductive probe is in contact with a conductive pad, a semiconductor wafer structure, and a method of producing a semiconductor device.

### BACKGROUND OF THE INVENTION

For a semiconductor device such as an LSI, an electrical test is performed before delivery to check whether the semiconductor device has defects or not. Such a test may be performed for a semiconductor chip produced by dicing a semiconductor wafer or may be performed for a wafer before dicing.

In any case, in the above test, a probe is placed on a conductive pad so that the probe of a probe card is in contact with the conductive pad provided on a semiconductor device. The test is performed by applying a voltage for the test to the probe. The probe is also referred to as a probe pin, a needle, or a cantilever.

A moderate pressure is applied to the probe. The probe is bent and slid by this application of pressure. The probe is electrically connected to the conductive pad in this state.

When the probe slides by a large amount, the probe is shifted and falls off from the conductive pad, and thus the test cannot be stably performed.

To solve this problem, in a known technique, a conductive pad having a concave cross-sectional shape is formed, thereby preventing a probe being shifted and falling off from a conductive pad (for example, see Japanese Patent Application Laid-Open No. Hei 9-260444 and No. 2006-32540).

Another technique different from the above technique is also known (for example, see Japanese Patent Application Laid-Open No. 2003-86589).

FIG. 1 is an enlarged cross-sectional view of the relevant part of a conductive pad and the periphery thereof disclosed in Japanese Patent Application Laid-Open No. 2003-86589.

In this semiconductor device, an interlayer insulating film 101 is provided above a semiconductor substrate 100. A conductive pad 102 including a copper-containing aluminum film 102a and a titanium nitride film 102b is provided on the interlayer insulating film 101.

A passivation film 103 such as a silicon oxide film is provided on the conductive pad 102. The surface of the conductive pad 102 is exposed through a window 103a, which is an opening formed in the passivation film 103.

In performing an electrical test, a probe 110 is brought into contact with the surface of the conductive pad 102. If the surface of the conductive pad 102 is hard, the probe 110 slides on the surface of the conductive pad 102 and contacts a side face of the window 103a. As a result, the passivation film 103 is damaged, thus causing a problem of the degradation of moisture resistance of the device.

Therefore, in general, the hard titanium nitride film 102b disposed in the window 103a is removed, and the aluminum film 102a, which is softer than the titanium nitride film 102b, is exposed, thereby preventing the sliding of the probe 110.

However, in this structure, when the probe 110 is slid on the upper surface of the conductive pad 102, the soft aluminum film 102a is scraped off. Consequently, a scraped residue 102c of aluminum tends to become adhered to the tip of the probe 110.

The residue 102c may enter between the conductive pad 102 and the probe 110, and contact failure between the conductive pad 102 and the probe 110 may occur. In addition, the residue 102c may become adhered to another semiconductor chip, and thus, the non-defective semiconductor chip may be determined to be a defective chip. Accordingly, it is believed that it is difficult to accurately perform an electrical test.

In FIG. 6 of Japanese Patent Application Laid-Open No. 2003-86589, a local recess is provided near the center of a conductive pad. According to this conductive pad structure, if the probe 110 fits in the recess during an electrical test, the sliding of the probe 110 can be prevented. However, in this conductive pad, the area of a flat portion is larger than the area of the recess. Therefore, it is believed that the probability that the probe 110 fits in the recess is small, that is, the probability that the probe 110 slides on the flat surface is large. Accordingly, there is a problem that the above-mentioned residue is easily generated.

Furthermore, in Japanese Patent Application Laid-Open No. 2004-63652, a bump is formed on a conductive pad, and a recess for fitting a probe is further formed on the upper surface of the bump, thereby preventing the probe from being shifted and falling off from the conductive pad. However, in this method of forming a bump, a step of forming the bump is necessary, and the production cost is increased accordingly.

As described above, in the related art, it is difficult to accurately perform an electrical test in a state in which a conductive probe is in contact with a conductive pad while damage of a passivation film is prevented.

### SUMMARY OF THE INVENTION

According to one aspect of the present invention, a semiconductor device comprises a conductive pad that is provided on the insulating film and that is obtained by forming a main conductive film and a surface conductive film harder than the main conductive film in that order.

### BRIEF DESCRIPTION OF THE DRAWINGS

A preferred embodiment of the present invention will be described with reference to the accompanying drawings, wherein:

FIG. 1 is an enlarged cross-sectional view of the relevant part of a conductive pad and the periphery thereof disclosed in Japanese Patent Application Laid-Open No. 2003-86589;

FIGS. 2A to 2K are cross-sectional views showing steps of producing a semiconductor wafer structure according to a first embodiment of the present invention;

FIG. 3 is an enlarged plan view of a pad area at the time of finishing the step shown in FIG. 2J in the first embodiment of the present invention;

FIG. 4 is an enlarged plan view of a semiconductor wafer structure according to the first embodiment of the present invention;

FIG. 5 is an enlarged cross-sectional view illustrating an electrical test performed in the first embodiment of the present invention;

FIG. 6 is an enlarged cross-sectional view in the case where wire bonding is performed for a semiconductor device according to the first embodiment of the present invention;

FIG. 7 is an enlarged cross-sectional view in the case where an external connection terminal is bonded to a semiconductor device according to the first embodiment of the present invention;

FIGS. 8A and 8B are cross-sectional views showing steps of producing a semiconductor wafer structure according to a second embodiment of the present invention;

FIG. 9 is an enlarged plan view of a pad area of the semiconductor wafer structure according to the second embodiment of the present invention;

FIGS. 10A and 10B are cross-sectional views showing steps of producing a semiconductor wafer structure according to a third embodiment of the present invention;

FIGS. 11A to 11C are cross-sectional views showing steps of producing a semiconductor wafer structure according to a fourth embodiment of the present invention;

FIGS. 12A to 12C are cross-sectional views showing steps of producing a semiconductor wafer structure according to a fifth embodiment of the present invention;

FIG. 13 is an enlarged plan view of a semiconductor wafer structure and a pad area of a semiconductor device according to a sixth embodiment of the present invention;

FIG. 14 is an enlarged plan view of another semiconductor wafer structure and a pad area of another semiconductor device according to the sixth embodiment of the present invention;

FIG. 15 is an enlarged plan view of a semiconductor wafer structure and a pad area of a semiconductor device according to a seventh embodiment of the present invention; and

FIG. 16 is an enlarged plan view of a semiconductor wafer structure and a pad area of a semiconductor device according to an eighth embodiment of the present invention.

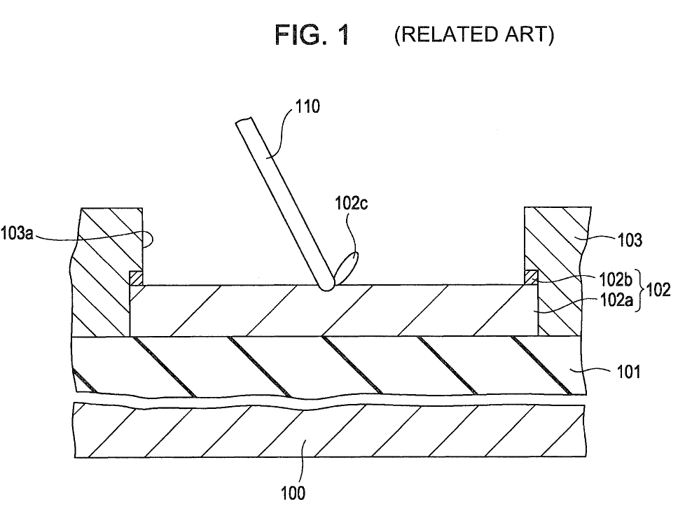

### DETAILED DESCRIPTION OF THE DRAWINGS

Embodiments of the present invention will now be described in detail with reference to the accompanying drawings.

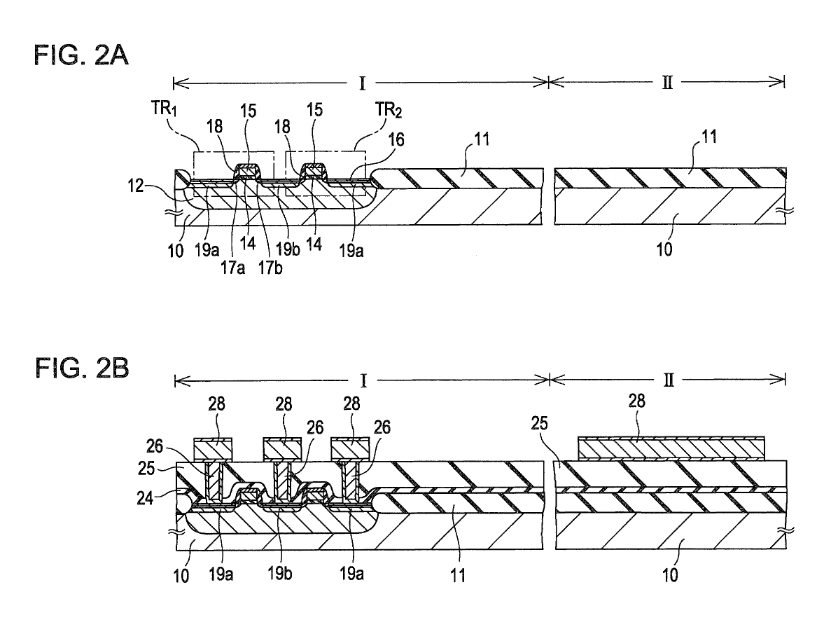

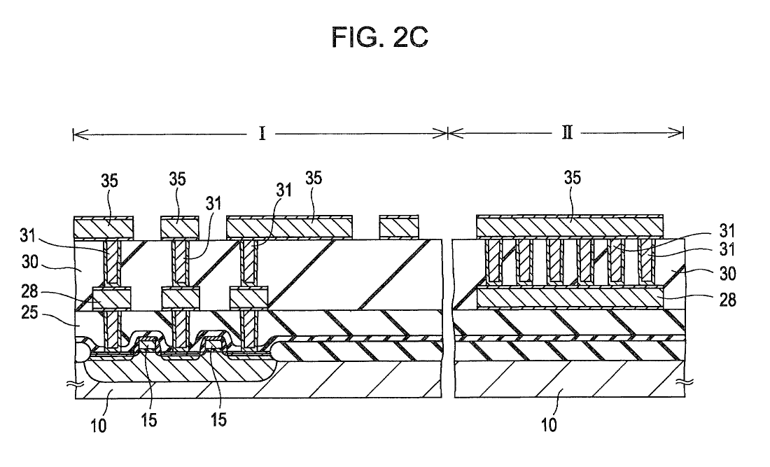

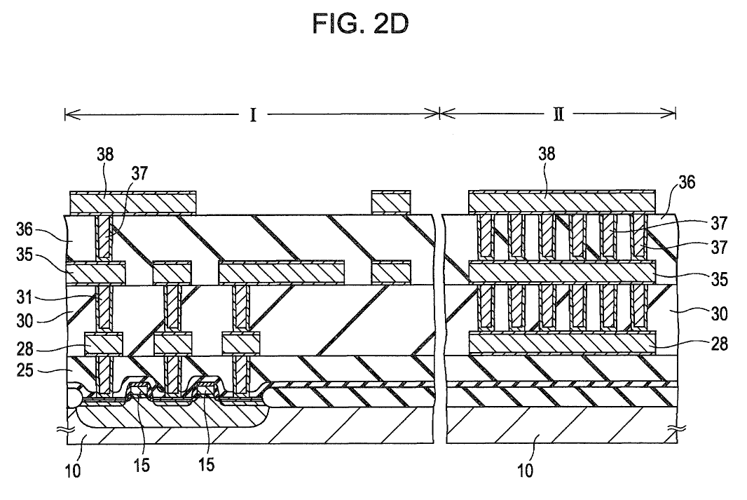

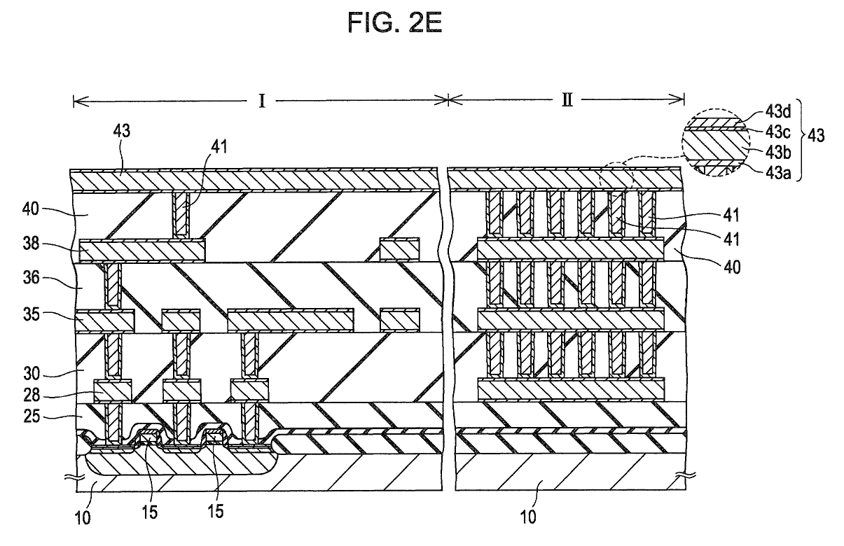

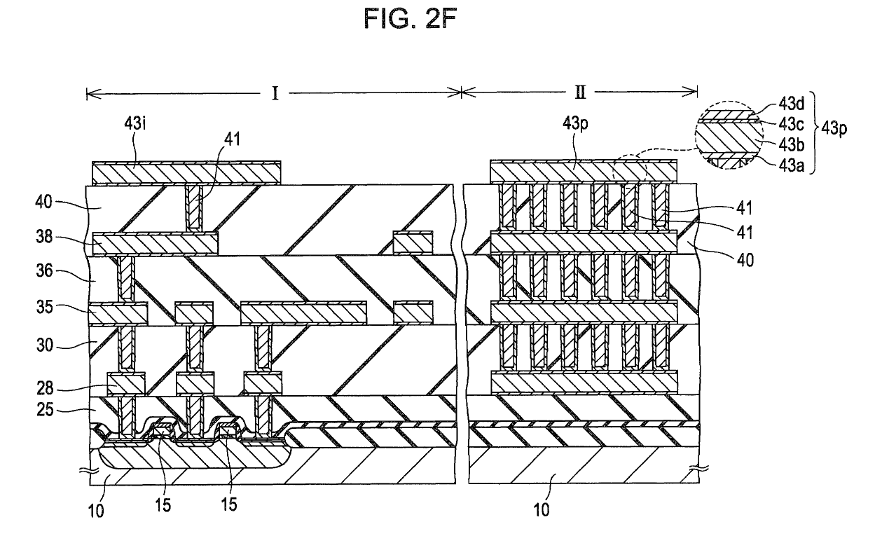

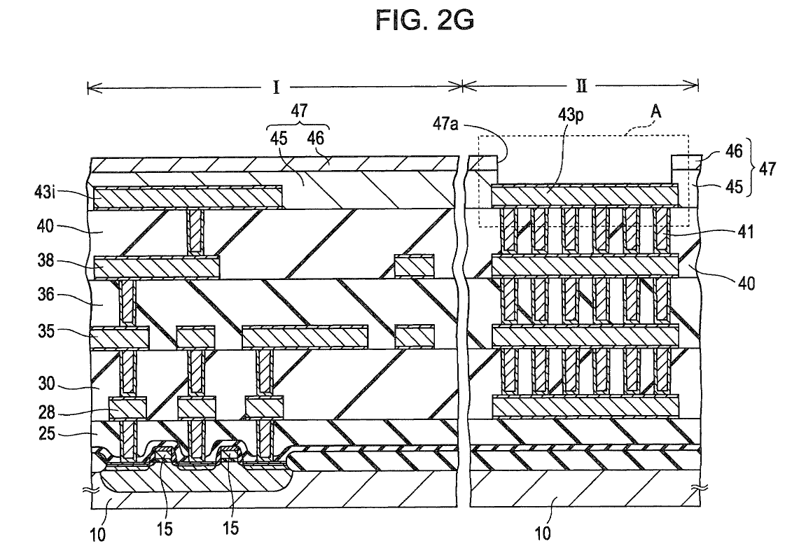

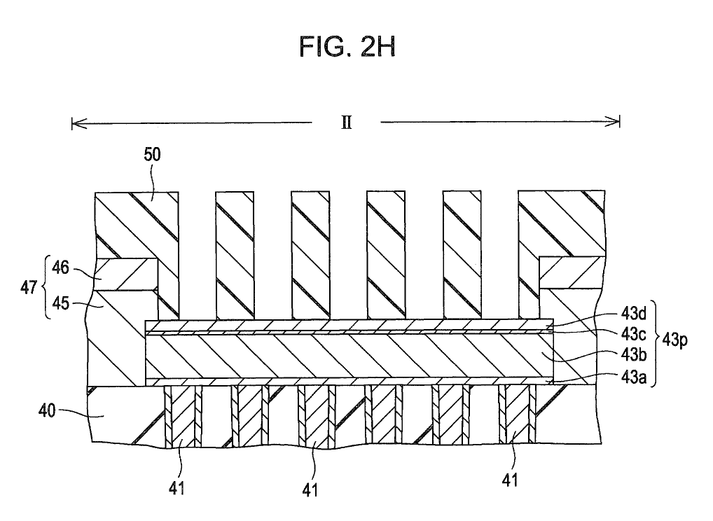

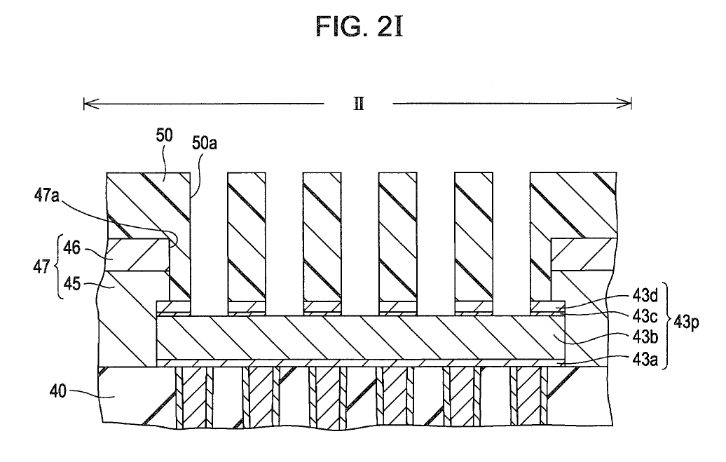

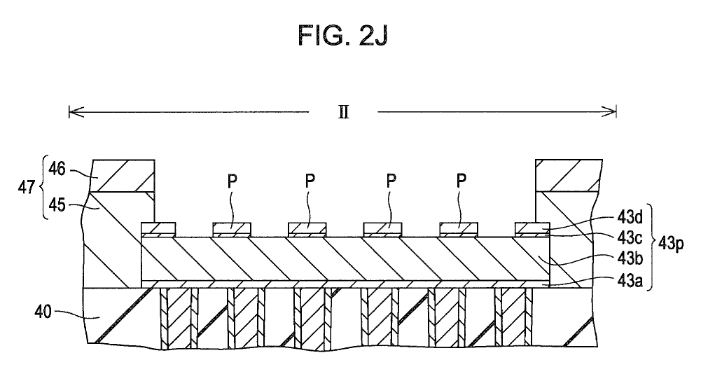

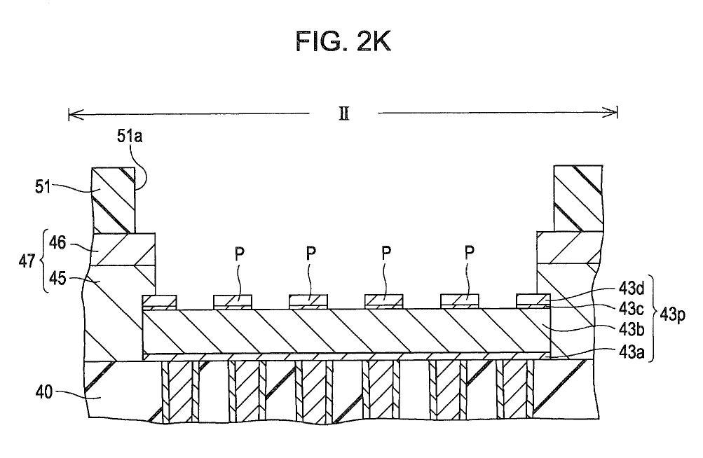

FIGS. 2A to 2K are cross-sectional views showing steps of producing a semiconductor wafer structure according to a first embodiment. Among these figures, each of FIGS. 2A to 2G shows both a circuit area I and a pad area II defined on a silicon substrate 10, and each of FIGS. 2H to 2K shows only the pad area II in an enlarged manner.

First, steps of producing the cross-sectional structure shown in FIG. 2A will be described.

First, a surface of an n-type or p-type silicon (semiconductor) substrate 10 is thermally oxidized to form an element isolation insulating film 11 for defining an active region of transistors. This element isolation structure is referred to as local oxidation of silicon (LOCOS). Alternatively, shallow trench isolation (STI) may be used instead of the above method.

Subsequently, a p-well 12 is formed by introducing a p-type impurity in the active region of the silicon substrate 10. The surface of the active region is then thermally oxidized to form a thermally oxidized film serving as a gate insulating film 14.

An amorphous or polycrystalline silicon film is then formed on the entire upper surface of the silicon substrate 10. After the silicon film is formed as described above, the film is patterned by photolithography to form gate electrodes 15.

Subsequently, ion implantation is performed using the gate electrodes 15 as a mask, and thus an n-type impurity is introduced in areas of the silicon substrate 10, the areas being located at both sides of each of the gate electrodes 15. Thus, first source/drain extensions 17a and second source/drain extensions 17b are formed.

Subsequently, an insulating film is formed on the entire upper surface of the silicon substrate 10. The insulating film is then etch-backed to form insulating side walls 18 at both sides of each of the gate electrodes 15. The insulating film is, for example, a silicon oxide film formed by a chemical vapor deposition (CVD) method.

Subsequently, an n-type impurity is again introduced in the silicon substrate 10 by ion implantation using the insulating side walls 18 and the gate electrodes 15 as a mask. By performing such an ion implantation, first source/drain regions 19a and a second source/drain region 19b are formed in areas on the surface layer of the silicon substrate 10, the areas being located at the lateral portions of the gate electrodes 15.

By performing the above-described steps, a first MOS transistor TR₁ and a second MOS transistor TR₂ each mainly composed of the gate insulating film 14, the gate electrode 15, the first source/drain region 19a, and the second source/drain region 19b are formed in the active region of the silicon substrate 10.

Next, a refractory metal layer such as a cobalt layer is formed on the entire upper surface of the silicon substrate 10 by a sputtering method. The refractory metal layer is then allowed to react with silicon by heating, thus forming a refractory metal silicide layer 16 on the silicon substrate 10. The refractory metal silicide layer 16 is formed also on the surface layer of the gate electrodes 15. The formation of this refractory metal silicide layer 16 can decrease the resistance of the gate electrodes 15.

The unreacted refractory metal layer disposed on the element isolation insulating film 11 and other portions is then removed by wet etching.

Next, as shown in FIG. 2B, a silicon oxynitride film functioning as a cover insulating film 24 is formed on the entire surface of the silicon substrate 10 by a plasma CVD method. This silicon oxynitride film is formed so as to have a thickness of, for example, about 200 nm. Furthermore, a silicon oxide film is grown as a first interlayer insulating film 25 on the cover insulating film 24 by a plasma CVD method using TEOS gas. This silicon oxide film is grown so as to have a thickness of, for example, about 1.0 μm. Subsequently, the first interlayer insulating film 25 is polished by a chemical mechanical polishing (CMP) method so that the upper surface of the first interlayer insulating film 25 is planarized.

Subsequently, the cover insulating film 24 and the first interlayer insulating film 25 are patterned by photolithography. By this patterning, contact holes are formed in these insulating films (i.e., the cover insulating film 24 and the first interlayer insulating film 25). These contact holes are located right on the first source/drain regions 19a and the second source/drain region 19b.

First conductive plugs 26 are then formed in the contact holes by sequentially forming a titanium film, a titanium nitride film, and a tungsten film.

A metal laminated film including a titanium nitride film, a copper-containing aluminum film, and a titanium nitride film is then formed on the upper surfaces of the first conductive plugs 26 and the first interlayer insulating film 25 by a sputtering method. The metal laminated film is then patterned to form a first metal wiring 28.

Next, as shown in FIG. 2C, a second interlayer insulating film 30 is formed on the first interlayer insulating film 25 and the first metal wiring 28. In this embodiment, the second interlayer insulating film 30 is, for example, a silicon oxide film. This silicon oxide film is formed by a CVD method using TEOS gas so as to have a thickness of, for example, about 2,200 nm.

Furthermore, the upper surface of the second interlayer insulating film 30 is polished by a CMP method to planarize the second interlayer insulating film 30. The second interlayer insulating film 30 is then patterned by photolithography to form holes on the first metal wiring 28.

Subsequently, a titanium nitride film functioning as a glue film is formed in the holes and on the upper surface of the second interlayer insulating film 30. This titanium nitride film is formed by, for example, a sputtering method so as to have a thickness of 50 nm. A tungsten film is then formed on the glue film by, for example, a CVD method. In this step, the tungsten film is formed so as to have a thickness of, for example, about 650 nm. The holes are completely filled with this tungsten film.

Unnecessary portions of the glue film and the tungsten film on the second interlayer insulating film 30 were then removed by polishing using a CMP method. These films are left in the holes, and the remaining portions function as second conductive plugs 31. Alternatively, instead of using a CMP method, the unnecessary portions of the glue film and the tungsten film may be removed by etch-back.

Subsequently, a titanium nitride film, a copper-containing aluminum film, and a titanium nitride film are formed by a sputtering method on the upper surfaces of the second conductive plugs 31 and the second interlayer insulating film 30 in that order. The formation of these films is performed by, for example, a sputtering method. These films are then patterned by photolithography to form a second metal wiring 35.

Next, as shown in FIG. 2D, a silicon oxide film functioning as a third interlayer insulating film 36 is formed on the second metal wiring 35 and the second interlayer insulating film 30. In this case, the thickness of the silicon oxide film is, for example, about 2,200 nm. The formation of this silicon oxide film is performed by, for example, a plasma CVD method using TEOS gas.

Subsequently, the upper surface of the third interlayer insulating film 36 is polished by a CMP method, and the third interlayer insulating film 36 is then patterned by photolithography. Accordingly, holes are formed in the third interlayer insulating film 36 located on the second metal wiring 35. Third conductive plugs 37 are formed in the holes by the same method as the above-described method of forming the second conductive plugs 31.

A third metal wiring 38 is then formed on the third conductive plugs 37 and the third interlayer insulating film 36 by the same method as the method of forming the second metal wiring 35.

Next, steps of forming the cross-sectional structure shown in FIG. 2E will be described.

First, a silicon oxide film is formed on the third metal wiring 38 and the third interlayer insulating film 36 by, for example, a plasma CVD method using TEOS gas. The thickness of this silicon oxide film is, for example, about 2,200 nm. The silicon oxide film thus formed functions as a fourth interlayer insulating film 40.

Subsequently, in order to planarize the upper surface of the fourth interlayer insulating film 40, chemical mechanical polishing (CMP) of the fourth interlayer insulating film 40 is performed. Holes are then formed in the fourth interlayer insulating film 40 located on the third metal wiring 38. These holes are formed by patterning the fourth interlayer insulating film 40 using photolithography.

Fourth conductive plugs 41 are then formed in the holes by the same method as the method of forming the second conductive plugs 31 or the third conductive plugs 37.

Subsequently, a conductive laminated film 43 is formed on the fourth conductive plugs 41 and the fourth interlayer insulating film 40 by a sputtering method.

The conductive laminated film 43 is obtained by forming, for example, a barrier metal film 43a, a main conductive film 43b, an adhesive film 43c, and a surface conductive film 43d in that order. More specifically, the barrier metal film 43a is composed of, for example, a titanium nitride film having a thickness of about 50 nm. The main conductive film 43b is composed of, for example, a copper-containing aluminum film (copper content: 0.5 weight percent) having a thickness of about 550 nm. The adhesive film 43c is composed of, for example, a titanium film having a thickness of about 5 nm. The surface conductive film 43d is composed of, for example, a titanium nitride film having a thickness in the range of 50 to 150 nm.

Among these films, the surface conductive film 43d functions as an antireflection film in a subsequent step of patterning the conductive laminated film 43 by photolithography. Therefore, the surface conductive film 43d may be composed of a titanium aluminum nitride (TiAlN) film instead of the above-mentioned titanium nitride film.

In both the case where titanium nitride is used and the case where titanium aluminum nitride is used, the surface conductive film 43d is harder than the main conductive film 43b made of copper-containing aluminum.

For the purpose of the description of the present invention, the hardness of a film can be determined on the basis of a value, for example, the Vickers hardness, measured by any single method.

The adhesive film 43c is a film that improves the adhesive strength between the main conductive film 43b and the surface conductive film 43d. When the adhesive strength is satisfactory, the formation of the adhesive film 43c may be omitted.

The barrier metal film 43a has a function of preventing the elements constituting the main conductive film 43b, such as aluminum and copper, from diffusing into the fourth interlayer insulating film 40, which is disposed under the barrier metal film 43a. When the possibility of the occurrence of the problem of this diffusion is low, the formation of the barrier metal film 43a may be omitted.

Subsequently, as shown in FIG. 2F, the conductive laminated film 43 is patterned by photolithography. Accordingly, a fourth wiring 43i is formed in the circuit area I, and in addition, a conductive pad 43p is formed in the pad area II.

In this embodiment, the conductive pad 43p functions as both a bonding pad and a test pad. In a semiconductor chip that has passed an electrical test described below, a bonding wire such as a gold wire is bonded to this conductive pad 43p. Alternatively, the bonding pad and the test pad may be separately formed according to need.

Next, as shown in FIG. 2G, a silicon oxide film 45 is formed on the fourth wiring 43i, the conductive pad 43p, and the fourth interlayer insulating film 40. The silicon oxide film 45 is formed by, for example, a plasma CVD method so as to have a thickness of, for example, about 200 nm.

Subsequently, in order to dehydrate the silicon oxide film 45 and to prevent the dehydrated moisture from being reabsorbed, a N₂O plasma treatment is performed on the silicon oxide film 45 using a CVD apparatus. The conditions for this N₂O plasma treatment are not particularly limited. For example, the substrate temperature is increased to 350° C. and this heating treatment is performed for two minutes.

Furthermore, a silicon nitride film 46 having a thickness of about 700 nm is formed on the silicon oxide film 45 by a plasma CVD method. By forming this silicon nitride film 46, a passivation film 47 composed of the silicon oxide film 45 and the silicon nitride film 46 can be formed.

The silicon nitride film 46 included in the passivation film 47 has an excellent moisture-blocking property. Therefore, the silicon nitride film 46 is a film suitable for the passivation film 47. However, the silicon nitride film 46 is a relatively hard film in which cracks are easily formed. Accordingly, as in this embodiment, preferably, the silicon oxide film 45 is formed as a film that reduces a stress, thereby preventing the formation of cracks in the silicon nitride film 46 due to a stress applied from the substrate side.

The passivation film 47 located on the conductive pad 43p is then etched using a resist pattern (not shown) as a mask with a plasma etching apparatus in which a mixed gas of CHF₃ and O₂ is used as an etching gas, thus forming a first opening(window) 47a through which the conductive pad 43p is exposed.

After this etching is finished, the resist pattern used as the mask is removed.

Next, subsequent steps will be described with reference to enlarged cross-sectional views of the pad area II surrounded by the rectangle A shown by the dotted line of FIG. 2G.

First, as shown in FIG. 2H, a photoresist is applied on the passivation film 47 and the conductive pad 43p. The photoresist is exposed and developed to form a resist pattern 50.

Subsequently, as shown in FIG. 2I, the surface conductive film 43d and the adhesive film 43c are selectively etched using the resist pattern 50 as a mask with a plasma etching apparatus in which a mixed gas of CF₄ and O₂ is used as an etching gas.

In this embodiment, the amount of etching in this step is controlled by changing the etching time, thereby the surface conductive film 43d and the adhesive film 43c located in areas that are not covered with the resist pattern 50 are completely removed, and the etching is stopped near the top surface of the main conductive film 43b.

Note that, in this embodiment, since side faces 50a of the resist pattern 50 are located inside the first opening 47a, the surface conductive film 43d that is present near the inside of the first opening 47a remains without being etched.

As shown in FIG. 2J, the resist pattern 50 is then removed. As a result, protruding portions P including the remaining surface conductive film 43d are formed on the top surface of the conductive pad 43p.

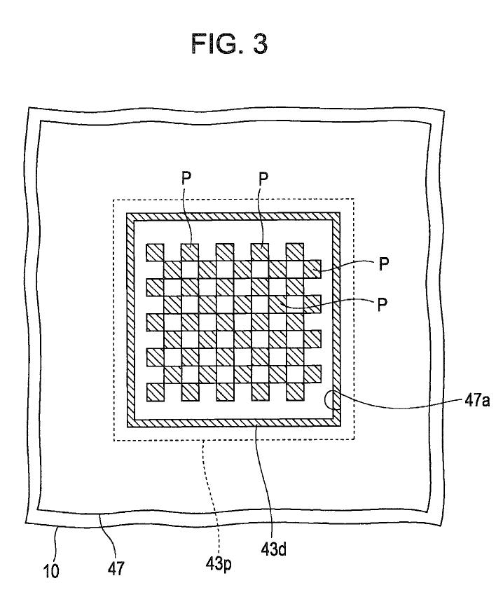

FIG. 3 is an enlarged plan view of the pad area II at the time of finishing this step.

As shown in FIG. 3, in this embodiment, the planar shape of the first opening 47a of the passivation film 47 is a square having a side of about 50 μm. Each of the protruding portions P has an island-like planar shape, and the protruding portions P are arranged in a checkered pattern.

The dimensions of each of the protruding portions P are not particularly limited. In this embodiment, each of the protruding portions P are formed so as to have a square shape having a side in the range of 3 to 10 μm.

Next, as shown in FIG. 2K, a photosensitive polyimide is applied on the passivation film 47 and the conductive pad 43p so as to have a thickness in the range of 1 to 3 μm, for example, 3 μm. The resulting photosensitive polyimide film is then exposed and developed. Accordingly, a protective film 51 having a second opening (window) 51a is formed on the conductive pad 43p.

The protective film 51 may be formed using a non-photosensitive polyimide instead of the photosensitive polyimide. In such a case, the non-photosensitive polyimide is applied, and the polyimide located on the conductive pad 43p is then selectively dissolved and removed using a resist pattern (not shown) as a mask with a dedicated developer. Thus, the second opening 51a is formed.

Subsequently, the protective film 51 is heat-treated for about 40 minutes using a horizontal furnace at a N₂ flow rate of 100 L/min and at a substrate temperature of 310° C. Accordingly, the polyimide constituting the protective film 51 is cured.

Thus, main steps of producing the semiconductor wafer structure of this embodiment are finished.

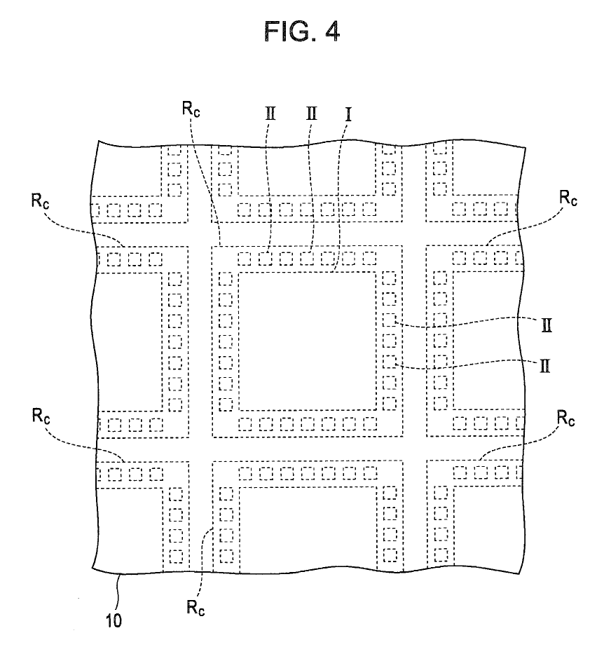

FIG. 4 is an enlarged plan view of this semiconductor wafer structure.

In FIG. 4, in order to prevent the figure from being complicated, only the silicon substrate 10 is shown.

As shown in FIG. 4, this semiconductor structure includes a plurality of chip areas Rc. The above-described circuit area I and the pad areas II are defined in each of the chip area Rc.

After this semiconductor structure is obtained, in order to check whether or not circuits formed in the chip areas Rc of the semiconductor wafer structure have designed characteristics, an electrical test is performed on the wafer level.

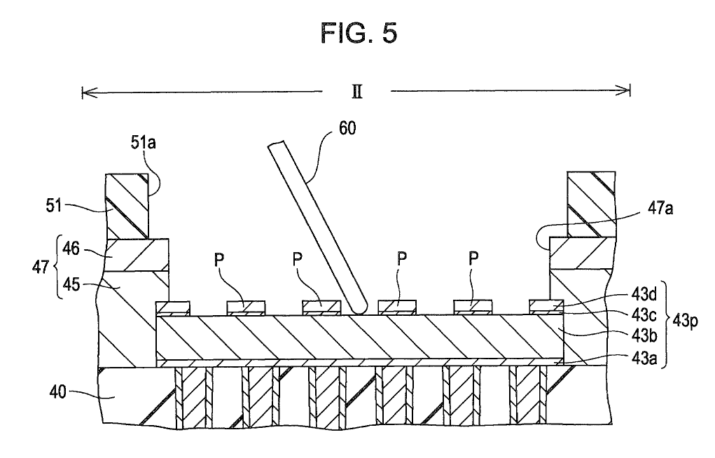

FIG. 5 is an enlarged cross-sectional view illustrating the test.

As shown in FIG. 5, in the test, a test voltage is applied from a conductive probe 60 to a circuit formed on the silicon substrate 10 in the circuit area I by bringing the probe 60 into contact with a conductive pad 43p.

Here, in this embodiment, the protruding portions P provided on the top surface of the conductive pad 43p function as slide-preventing means of the probe 60. Accordingly, the amount of sliding of the probe 60 on the top surface of the conductive pad 43p is regulated by the presence of the protruding portions P.

Therefore, the aluminum-containing soft main conductive film 43b exposed between the protruding portions P is not easily scraped off by the probe 60. As a result, a residue of the conductive pad 43p generated by the scraping does not easily become adhered to the probe 60. Consequently, contact failure between the conductive pad 43p and the probe 60 due to the residue can be prevented, and thus, the electrical test can be accurately performed.

In addition, since the movement of the probe 60 is regulated by the presence of the protruding portions P, the phenomenon in which the probe 60 contacts the first opening 47a, thus damaging the passivation film 47 can be prevented. Accordingly, the blocking effect of moisture by the passivation film 47 can be maintained.

Furthermore, in order to form the protruding portions P, bumps described in Japanese Patent Application Laid-Open No. 2004-63652 need not be formed. As a result, the production cost can be reduced compared with that of the semiconductor device disclosed in Japanese Patent Application Laid-Open No. 2004-63652.

After the electrical test is performed, dicing is performed along scribe areas disposed between the chip areas Rc shown in FIG. 4. Thus, a plurality of semiconductor chips (semiconductor devices) are cut out from the above semiconductor wafer structure.

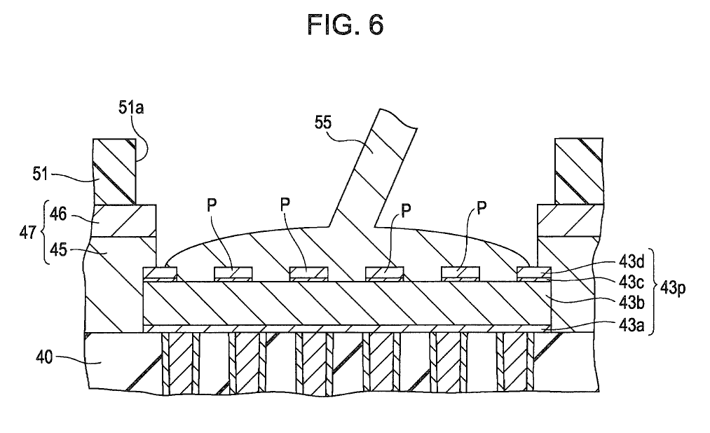

Subsequently, as shown in FIG. 6, a bonding wire 55 such as a gold wire is bonded to the conductive pad 43p by wire bonding.

In this case, since the protruding portions P are provided on the top surface of the conductive pad 43p, the contact area between the end of the bonding wire 55 and the conductive pad 43p can be increased. This structure can improve the adhesive strength between the bonding wire 55 and the conductive pad 43p. Consequently, a semiconductor device having high reliability can be provided.

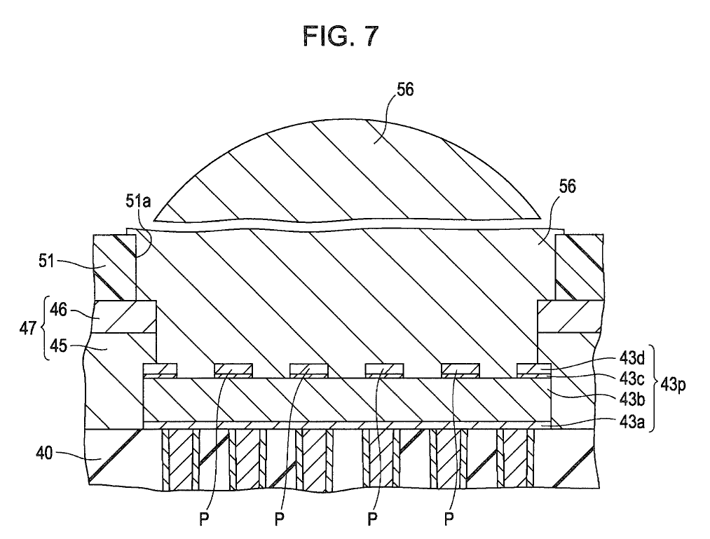

Instead of the bonding wire 55, an external connection terminal 56 such as a solder bump shown in FIG. 7 may be bonded to the conductive pad 43p. This structure can also improve the adhesive strength between the external connection terminal 56 and the conductive pad 43p by the presence of the protruding portions P.

Structures of a second embodiment to a seventh embodiment, which will be described below, can also improve the adhesive strength between the conductive pad 43p and the bonding wire 55 or the external connection terminal 56.

Thus, main steps of this embodiment are finished.

A second embodiment to a seventh embodiment of the present invention will now be described. In these embodiments, a method of producing a semiconductor wafer structure will be described. A plurality of semiconductor chips (semiconductor devices) can be obtained by dicing the resulting semiconductor wafer structure as in the first embodiment.

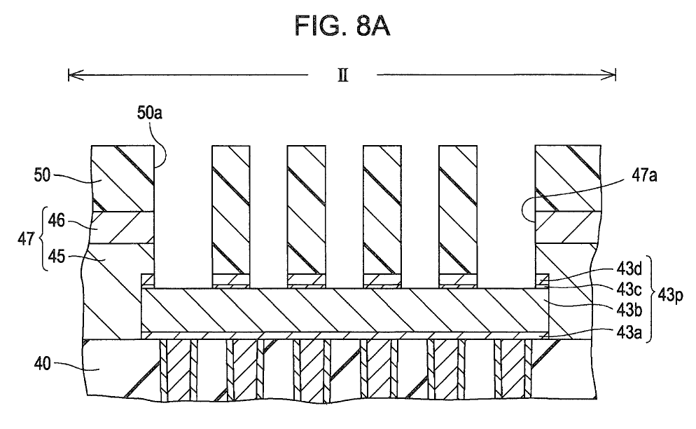

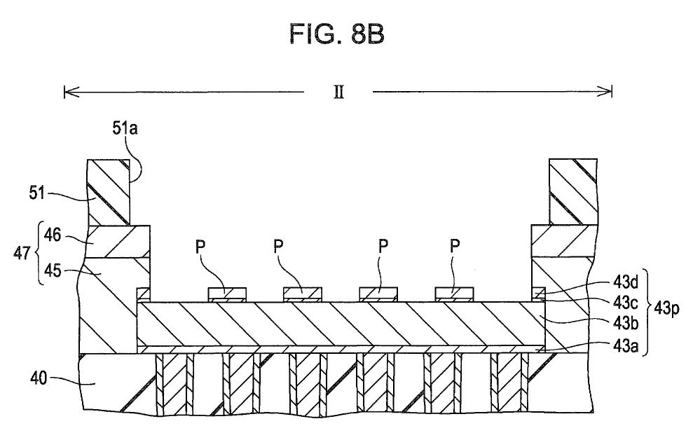

FIGS. 8A and 8B are cross-sectional views showing steps of producing a semiconductor wafer structure according to a second embodiment. This semiconductor wafer structure is produced as follows.

First, the steps shown in FIGS. 2A to 2G of the first embodiment are performed. As shown in FIG. 8A, a resist pattern 50 is then formed on a passivation film 47 and a conductive pad 43p.

In this second embodiment, side faces 50a of the resist pattern 50 are aligned with side faces of a first opening 47a. On the other hand, in the first embodiment, the side faces 50a are located inside the first opening 47a (see FIG. 2I). The second embodiment differs from the first embodiment in this point.

An adhesive film 43c and a surface conductive film 43d are selectively etched using the resist pattern 50 as a mask under the same etching conditions as those used in the first embodiment.

Since the side faces 50a of the resist pattern 50 are aligned with the side faces of the first opening 47a as described above, the adhesive film 43c and the surface conductive film 43d that are adjacent to the side faces of the first opening 47a are removed by this etching.

The resist pattern 50 is then removed, and the steps described in FIG. 2K are performed. By performing these steps, as shown in FIG. 8B, a semiconductor wafer structure including a conductive pad 43p having protruding portions P thereon can be produced.

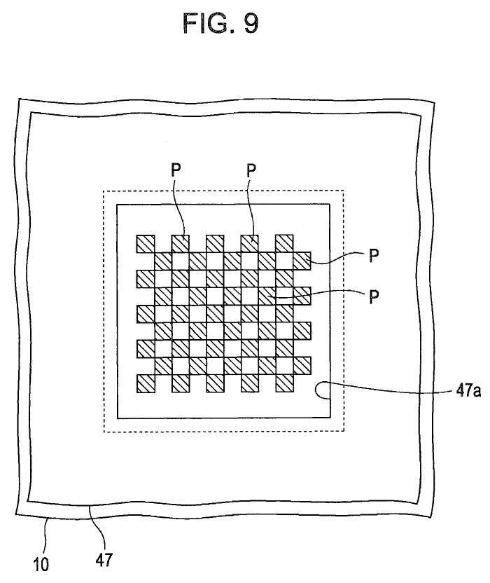

FIG. 9 is an enlarged plan view of a pad area II of this semiconductor wafer structure.

As shown in FIG. 9, in this embodiment, the surface conductive film 43d is not exposed near the inside the first opening 47a. Such a planar layout of the surface conductive film 43d can be used in third to seventh embodiments described below.

In contrast, in the planar layout of the first embodiment shown in FIG. 3, the surface conductive film 43d is exposed near the inside of the first opening 47a. As a result, the strength of the passivation film 47 near the first opening 47a is improved by the presence of the surface conductive film 43d.

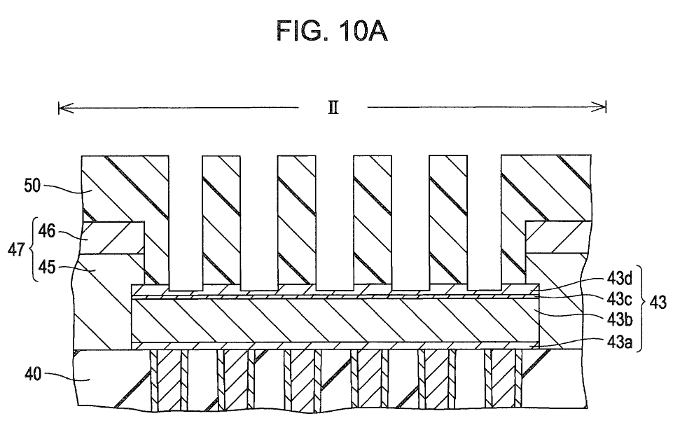

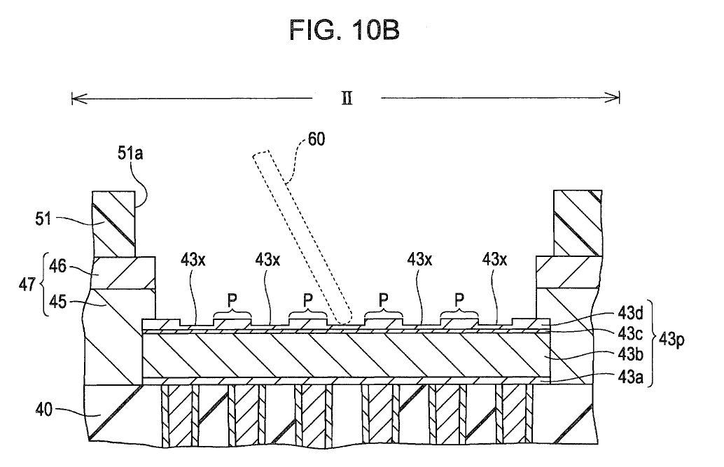

FIGS. 10A and 10B are cross-sectional views showing steps of producing a semiconductor wafer structure according to a third embodiment. This semiconductor wafer structure is produced as follows.

First, the steps shown in FIGS. 2A to 2I of the first embodiment are performed. As shown in FIG. 10A, a surface conductive film 43d is etched using a resist pattern 50 as a mask.

In this embodiment, however, the etching is stopped at a halfway position in the thickness direction of the surface conductive film 43d by decreasing the etching time, as compared with that in the first embodiment. Such etching is also referred to as half-etching.

After the resist pattern 50 is removed, a protective film 51 is formed in accordance with the above-described steps shown in FIG. 2K. As a result, the semiconductor wafer structure shown in FIG. 10B is produced.

In this embodiment, since half-etching is performed for the surface conductive film 43d, a plurality of recesses 43x are formed on the surface conductive film 43d. Accordingly, protruding portions P are formed by protrusions of the surface conductive film 43d disposed between the recesses 43x.

The planar layout of the protruding portions P is not particularly limited. For example, the protruding portions P can be arranged in the form of a plurality of islands as illustrated in FIGS. 3 and 9.

This structure can also prevent the scraping of the conductive pad 43p by a probe 60 because the protruding portions P function as slide-preventing means of the probe 60.

Furthermore, in this embodiment, the soft main conductive film 43b is not exposed between the protruding portions P. Therefore, the probe 60 is constantly in contact with the surface conductive film 43d, which is harder than the main conductive film 43b. Accordingly, the phenomenon in which the conductive pad 43p is scraped off by the probe 60 can be effectively prevented, compared with the case of the first embodiment in which the probe 60 is in contact with the main conductive film 43b.

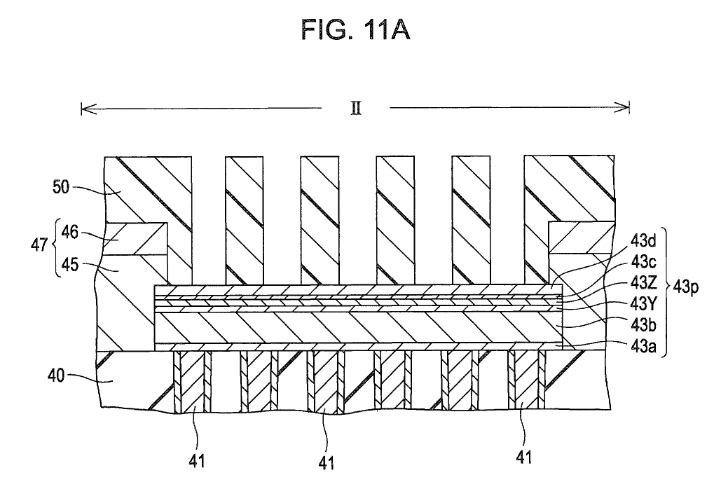

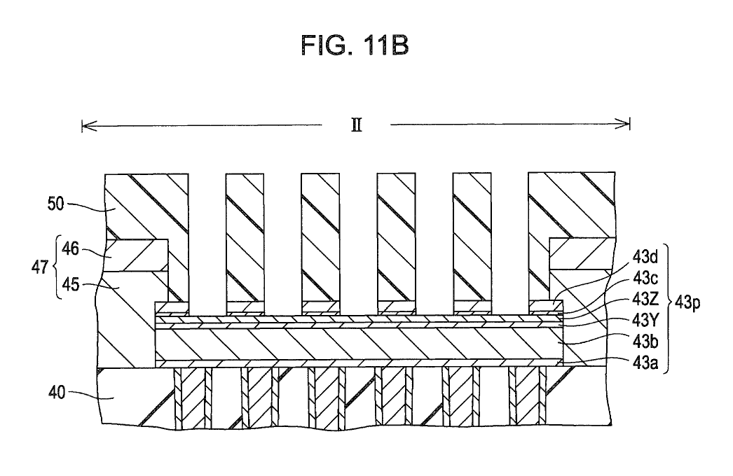

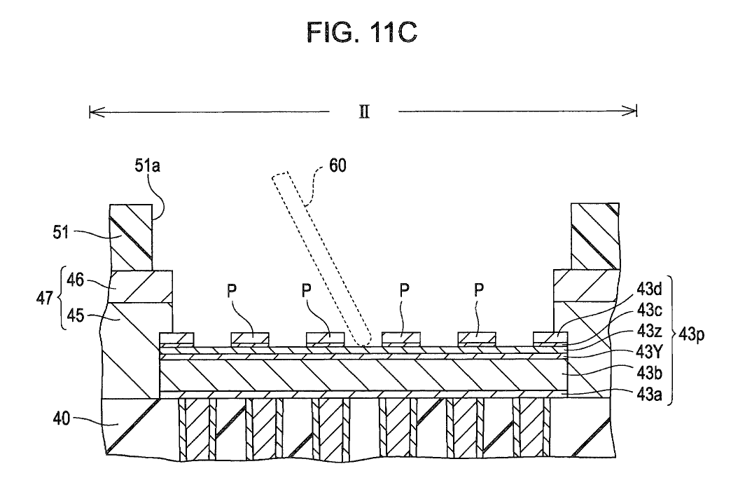

FIGS. 11A to 11C are cross-sectional views showing steps of producing a semiconductor wafer structure according to a fourth embodiment.

In this embodiment, as shown in FIG. 11A, an intermediate conductive film 43Y and a buffer conductive film 43Z are formed between a main conductive film 43b and an adhesive film 43c in that order. Here, the main conductive film 43b is composed of, for example, a copper-containing aluminum film having a thickness of about 350 nm, and the adhesive film 43c is composed of, for example, a titanium film having a thickness of about 5 nm.

The intermediate conductive film 43Y is made of a material harder than the main conductive film 43b. For example, a titanium nitride film having a thickness of about 100 nm can be formed as the intermediate conductive film 43Y. In addition to the titanium nitride film, a titanium aluminum nitride film is also included in examples of a film harder than the main conductive film 43b. The intermediate conductive film 43Y may be composed of a titanium aluminum nitride film.

In order to increase the adhesiveness between the intermediate conductive film 43Y and the main conductive film 43b, an adhesive film, such as a titanium film, having a thickness of about 5 nm is preferably formed between the intermediate conductive film 43Y and the main conductive film 43b.

The buffer conductive film 43Z is made of a material softer than the intermediate conductive film 43Y. For example, a copper-containing aluminum film having a thickness in the range of 50 to 100 nm is formed as the buffer conductive film 43Z.

The conductive pad 43p having the above layer structure can be formed by the following methods. First, the films 43a to 43d, the film 43Y, and the film 43Z are formed in the order shown in FIG. 11A by a sputtering method, more specifically, by the same method as that including the steps of forming the conductive laminated film 43 described with reference to FIG. 2E. As a result, the conductive laminated film 43 is formed. Subsequently, the conductive laminated film 43 is patterned by the same method as that including the steps described with reference to FIG. 2F. The conductive pad 43p is formed by these methods.

As shown in FIG. 11A, a resist pattern 50 is then formed on the conductive pad 43p and a passivation film 47.

Subsequently, as shown in FIG. 11B, the adhesive film 43c and the surface conductive film 43d having a thickness of about 150 nm are selectively etched using the resist pattern 50 as a mask. The etching conditions in this step are omitted because the conditions are the same as those described in the step shown in FIG. 2I.

After the resist pattern 50 is removed, as shown in FIG. 11C, a protective film 51 is formed on the passivation film 47 as described in the above embodiment to produce the semiconductor wafer structure of this embodiment.

The planar layout of protruding portions P in this embodiment is not particularly limited. For example, the protruding portions P can be arranged in the form of a plurality of islands as illustrated in FIGS. 3 and 9.

In this embodiment, as shown in FIG. 11C, the intermediate conductive film 43Y, which is harder than the main conductive film 43b, is provided. Therefore, even when a probe 60 is brought into contact with the conductive pad 43p during an electrical test, the intermediate conductive film 43Y prevents the probe 60 from penetrating into the main conductive film 43b. As a result, the phenomenon in which a large scraped residue is generated by scraping the conductive pad 43p with the probe 60 can be prevented.

Furthermore, since the soft buffer conductive film 43Z is provided on the intermediate conductive film 43Y, the probe 60 can penetrate into the buffer conductive film 43Z to a moderate depth thereinto. Consequently, the contact resistance between the probe 60 and the conductive pad 43p can be decreased.

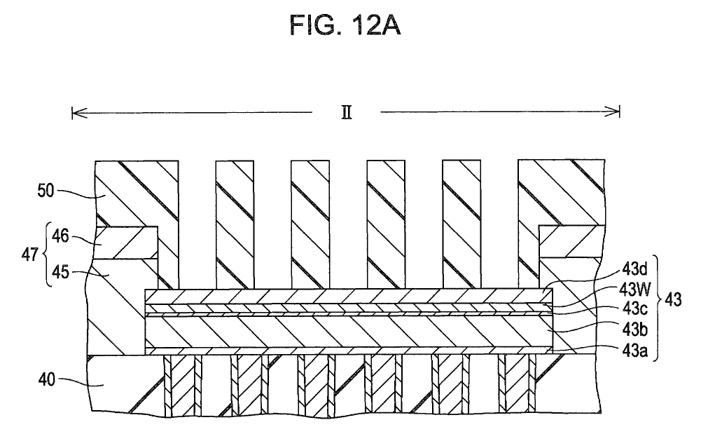

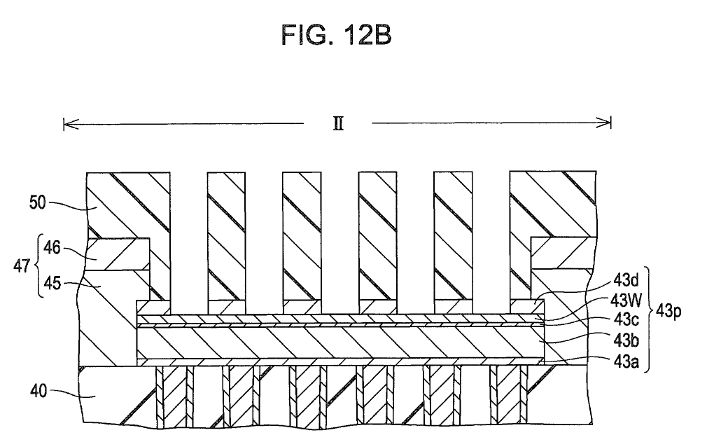

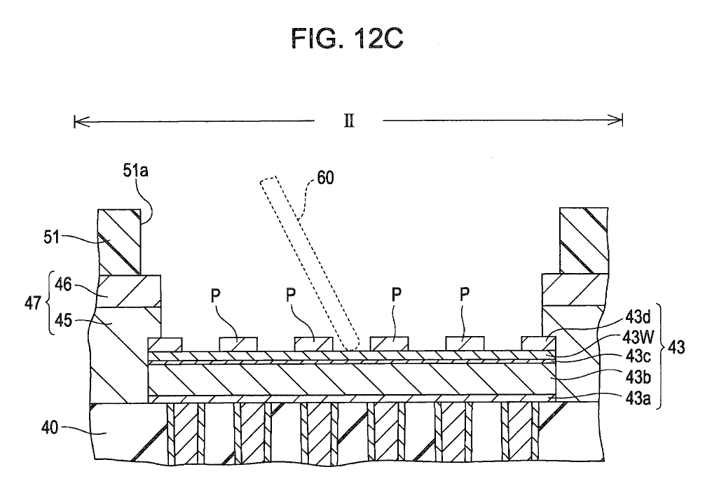

FIGS. 12A to 12C are cross-sectional views showing steps of producing a semiconductor wafer structure according to a fifth embodiment.

In this embodiment, as shown in FIG. 12A, a noble metal-containing conductive film 43W is formed between an adhesive film 43c having a thickness of about 5 nm and a surface conductive film 43d having a thickness of about 150 nm.

This noble metal-containing conductive film 43W is formed on the adhesive film 43c prior to the formation of the surface conductive film 43d in the steps of forming the conductive laminated film 43 described with reference to FIG. 2E. The formation of this noble metal-containing conductive film 43W is performed by, for example, a sputtering method. The material of the noble metal-containing conductive film 43W is not particularly limited, but, for example, platinum can be used. In this embodiment, a platinum film is formed so as to have a thickness in the range of, for example, 5 to 50 nm, and more preferably in the range of, for example, 20 to 50 nm.

Another noble metal film such as an iridium film, an osmium film, a ruthenium film, a rhodium film, or a palladium film may be formed instead of the platinum film.

Furthermore, instead of using such a pure noble metal film, a conductive noble-metal oxide film such as a platinum oxide (PtO) film or an iridium oxide (Irox) film may be used as the material of the noble metal-containing conductive film 43W.

A resist pattern 50 is then formed on a passivation film 47 and a conductive pad 43p.

Subsequently, as shown in FIG. 12B, the surface conductive film 43d is selectively etched using the resist pattern 50 as a mask with a plasma etching apparatus in which a mixed gas of CF₄ and O₂ is used as an etching gas.

In this etching, the noble metal-containing conductive film 43W, which has a low chemical reactivity, functions as an etching stopper film. Therefore, the amount of etching can be controlled easier than the case where the amount of etching is controlled by changing the etching time.

After the resist pattern 50 is removed, as shown in FIG. 12C, a protective film 51 is formed on the passivation film 47 as described in the above embodiment to produce the semiconductor wafer structure of this embodiment.

The planar layout of protruding portions P in this embodiment is not particularly limited. For example, the protruding portions P can be arranged in the form of a plurality of islands as illustrated in FIGS. 3 and 9.

In this embodiment described above, since the noble metal-containing conductive film 43W functioning as a stopper of etching has a low electrical resistance, this structure is further advantageous in that the conductive property of the conductive pad 43p can be improved.

Furthermore, as shown in FIG. 12C, since the noble metal-containing conductive film 43W, which is harder than the main conductive film 43b, is exposed on the surface of the conductive pad 43p without being etched, the scraping of the conductive pad 43p by a probe 60 can be prevented. Accordingly, during an electrical test, the generation of a residue from the conductive pad 43p can be suppressed.

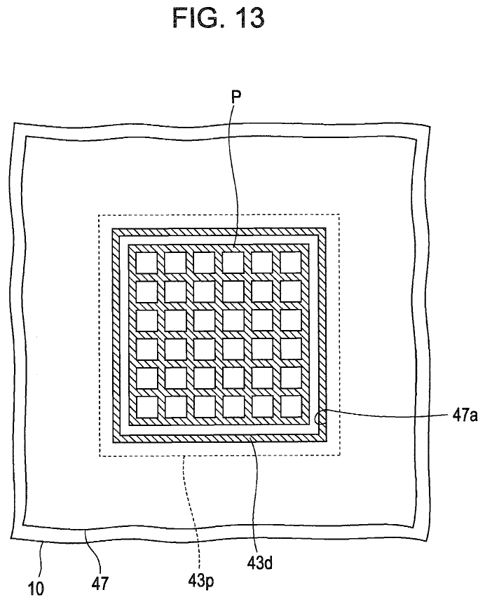

FIG. 13 is an enlarged plan view of a semiconductor wafer structure and a pad area II of a semiconductor device according to a sixth embodiment.

In this embodiment, the planer shape of the protruding portions P formed as in the first to fifth embodiments has a grid-shaped pattern shown in FIG. 13.

By forming such a grid-shaped pattern, all the protruding portions P are integrally connected to each other. Therefore, the mechanical strength of the protruding portions P can be improved, and in addition, separation of the protruding portions P from the fourth interlayer insulating film 40, which is disposed under the conductive laminated film 43, can be suppressed compared with the layout of the first embodiment in which the protruding portions P are isolated from each other (FIG. 3).

As a result, even when a probe 60 is brought into contact with the conductive pad 43p during an electrical test, separation of the protruding portions P due to a force applied by the probe 60 can be suppressed. Accordingly, the effect of preventing a sliding of the probe 60 due to the presence of the protruding portions P can be reliably achieved.

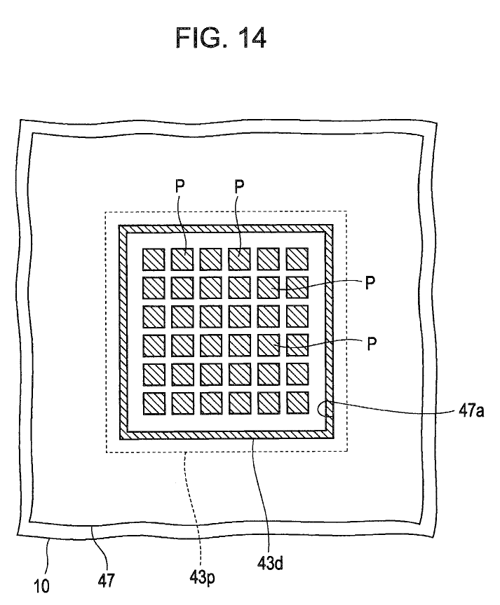

When the possibility of the occurrence of the problem of separation of the protruding portions P is low, as shown in FIG. 14, the planar shape of the protruding portions P may be a reverse arrangement of the above grid-shaped pattern.

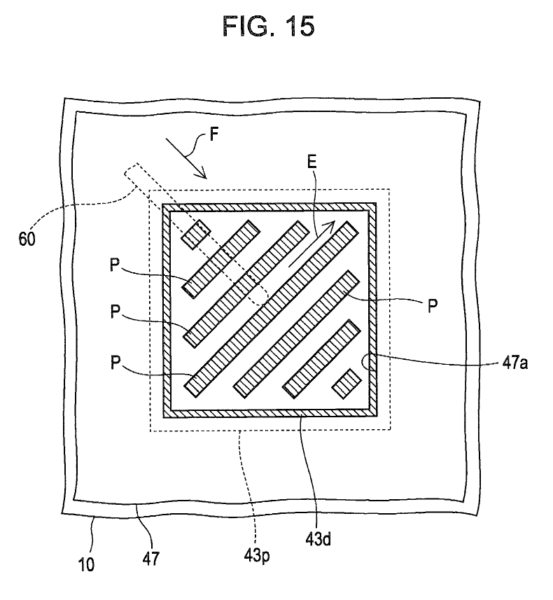

FIG. 15 is an enlarged plan view of a semiconductor wafer structure and a pad area II of a semiconductor device according to a seventh embodiment.

In this embodiment, as shown in FIG. 15, a plurality of protruding portions P are formed so that the planar shape of each of the protruding portions P is a strip shape. In addition, an extending direction E of the strip-shaped protruding portions P is made to be perpendicular to an entering direction F of a probe 60. Note that the term “entering direction F” means a moving direction of the probe 60 immediately before the probe 60 is brought into contact with a conductive pad 43p.

In the embodiment shown in FIG. 15, the planar shape of a opening 47a is a rectangle, and the entering direction F is diagonal with respect to each side of the rectangle.

This structure maximizes the force for blocking the movement of the probe 60 by the presence of the protruding portions P and suppresses the sliding of the probe 60 in the extending direction E. Consequently, the amount of sliding of the probe 60 can be minimized, and the amount of conductive pad 43p scraped off by the probe 60 can be reduced.

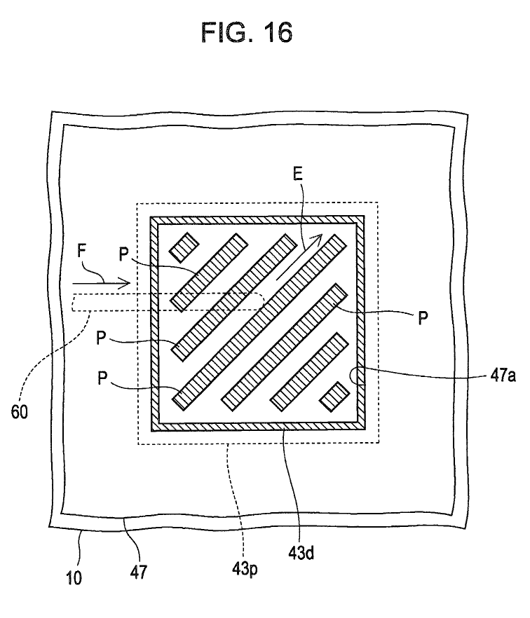

FIG. 16 is an enlarged plan view of a semiconductor wafer structure and a pad area II of a semiconductor device according to an eighth embodiment.

In this embodiment, as shown in FIG. 16, a plurality of protruding portions P are formed so that the planar shape of each of the protruding portions P is a strip shape. Furthermore, a surface conductive film 43d is exposed at the inside edge of a first opening 47a. Accordingly, the surface conductive film 43d functions as a shield ring for protecting the side faces of the first opening 47a from a probe 60.

The angle formed by an extending direction E of the strip-shaped protruding portions P and an entering direction F of the probe 60 is adjusted to about 45 degrees. In this case, since the probe 60 easily slides along the extending direction E, a force that acts from the probe 60 to a protruding portion P can be released.

Embodiments of the present invention have been described in detail, but the present invention is not limited to the above embodiments. For example, in the above embodiments, an electrical test is performed on the wafer level. Alternatively, the test may be performed for each semiconductor chip obtained after dicing.

As described above, according to the embodiments of the present invention, when an electrical test is performed for a circuit formed on a semiconductor substrate, protruding portions that are composed of a hard surface conductive film and that are formed on a conductive pad function as slide-preventing means of a probe. Consequently, the amount of sliding of the probe on the top surface of the conductive pad can be regulated by the protruding portions.

Accordingly, since the scraping of a soft main conductive film included in the conductive pad by the probe can be suppressed, a residue of the conductive pad generated by the scraping does not easily become adhered to the probe. As a result, contact failure between the conductive pad and the probe caused by the adhesion of the residue can be prevented, and the electrical test can be accurately performed.

In addition, since the movement of the probe is regulated by the presence of the protruding portions, the phenomenon in which the probe contacts an opening of a passivation film, thereby damaging the passivation film can be prevented. Accordingly, the blocking effect of moisture by the passivation film can be maintained.

What is claimed is:

1. A semiconductor device comprising:
a semiconductor substrate;
an insulating film provided over the semiconductor substrate;
a conductive pad that is provided on the insulating film and that is obtained by forming a main conductive film and a surface conductive film harder than the main conductive film in that order; and
a passivation film that is provided on the insulating film and that has an opening through which the conductive pad is exposed,
wherein the surface conductive film has at least one protruding portion.

2. The semiconductor device according to claim 1,
wherein the surface conductive film is selectively removed so that a surface of the main conductive film is partly exposed, and the remaining part of the surface conductive film constitutes the protruding portion.

3. The semiconductor device according to claim 2, further comprising:
an intermediate conductive film and a buffer conductive film provided between the main conductive film and the surface conductive film, wherein
the intermediate conductive film is provided on the main conductive film and is harder than the main conductive film, and
the buffer conductive film that is provided on the intermediate conductive film and that is softer than the intermediate conductive film.

4. The semiconductor device according to claim 2, further comprising:
a noble metal-containing conductive film provided between the main conductive film and the surface conductive film.

5. The semiconductor device according to claim 1,
wherein the surface conductive film has a plurality of recesses and protrusions, and each of the protrusions constitutes the protruding portion.

6. The semiconductor device according to claim 1,
wherein the surface conductive film has a plurality of protruding portions, the plurality of protruding portions are arranged in an island-like form.

7. The semiconductor device according to claim 1,
wherein a planar shape of the protruding portion is a grid shape.

8. The semiconductor device according to claim 1, wherein
the opening has a polygon shape,
the surface conductive film has a plurality of protruding portions, and
the plurality of protruding portions are provided in the form of strip-shaped portions each extending obliquely with respect to at least one side of the polygon.

9. The semiconductor device according to claim 1, further comprising:
a bonding wire or an external connection terminal,
wherein the bonding wire or the external connection terminal is bonded to the conductive pad.

10. The semiconductor device according to claim 1,
wherein the main conductive film comprises aluminum and the surface conductive film comprises titanium nitride or titanium aluminum nitride.

11. A semiconductor wafer structure comprising:
a semiconductor substrate in which a chip area is defined;
an insulating film provided over the semiconductor substrate;
a conductive pad provided on the insulating film in the chip area and the conductive pad is obtained by forming a main conductive film and a surface conductive film harder than the main conductive film in that order; and
a passivation film provided on the insulating film and the passivation film has an opening through which the conductive pad is exposed,
wherein at least one protruding portion including the surface conductive film is provided on the surface of the main conductive film.

12. The semiconductor wafer structure according to claim 11,
wherein the surface conductive film has a plurality of protruding portions, the plurality of protruding portions are arranged in an island-like form.

13. The semiconductor wafer structure according to claim 11,
wherein a planar shape of the protruding portion is a grid shape.

14. The semiconductor wafer structure according to claim 11, wherein
the opening has a polygon shape,
the surface conductive film has a plurality of protruding portions, and
the plurality of protruding portions are provided in the form of strip-shaped portions each extending obliquely with respect to at least one side of the polygon.

15. A method of producing a semiconductor device comprising:
forming an insulating film over a semiconductor substrate;
forming a conductive laminated film on the insulating film, the conductive laminated film including a main conductive film and a surface conductive film harder than the main conductive film, by forming the main conductive film and the surface conductive film in that order;
patterning the conductive laminated film to form a conductive pad;
forming a passivation film on the insulating film, the passivation film including an opening on the conductive pad;
forming a resist pattern on the conductive pad;
forming at least one protruding portion including the surface conductive film by selectively etching the surface conductive film;
removing the resist pattern; and
after the removal of the resist pattern, performing an electrical test of a circuit formed on the semiconductor substrate by bringing a conductive probe into contact with the conductive pad.

16. The method of producing a semiconductor device according to claim 15,
wherein the step of forming at least one protruding portion comprises removing the surface conductive film located in areas that are not covered with the resist pattern using the resist pattern as a mask, and
the remaining surface conductive film is used as the at least one protruding portion.

17. The method of producing a semiconductor device according to claim 16,
wherein, in the step of forming a conductive laminated film, an intermediate conductive film harder than the main conductive film and a buffer conductive film softer than the intermediate conductive film are formed on the main conductive film in that order, and
the surface conductive film is formed on the buffer conductive film.

18. The method of producing a semiconductor device according to claim 16,
wherein, in the step of forming a conductive laminated film, a noble metal-containing conductive film is formed on the main conductive film and the surface conductive film is formed on the noble metal-containing conductive film, and
in the step of forming at least one protruding portion, the surface conductive film is etched while the noble metal-containing conductive film is used as an etching stopper.

19. The method of producing a semiconductor device according to claim 15,
wherein, in the step of forming at least one protruding portion, a plurality of recesses are formed on the surface conductive film by etching the surface conductive film to a halfway position of the surface conductive film in the thickness direction, and
each of resulting protrusions is used as the protruding portion.

20. The method of producing a semiconductor device according to claim 15,
wherein, in the step of forming at least one protruding portion, the protruding portion is formed in the form of strip-shaped portion, and
in the step of performing an electrical test, an entering direction of the probe is made to be substantially perpendicular with respect to an extending direction of the protruding portion.
